(19) United States
(12) Patent Application Publication
(10) Pub. No.: US 2004/0037050 A1
(43) Pub. Date: Feb. 26, 2004

(54) Printed circuit board

(75) Inventors: Teruo Nakayama, Nagano (JP); Hideaki Inadachi, Nagano (JP)

Correspondence Address: SUGHRUE MION, PLLC, 2100 Pennsylvania Avenue, NW, Washington, DC, 20037-3213, US

(73) Assignee: SEIKO EPSON CORPORATION

(21) Appl. No.: 10/406,566

(22) Filed: Apr. 4, 2003

(30) Foreign Application Priority Data
Apr. 4, 2002 (JP) P2002-102948
Apr. 4, 2003 (JP) P2003-101729

(51) Int. Cl. H05K 1/14

(52) U.S. Cl. 361/736

(57) ABSTRACT

A trace array on a print d wiring board for optimally controlling an impedance of differential signal lines is provided.

A trace 2 connected to a line maintained at a fixed potential is arranged between a pair of signal traces 1 for transmitting differential signals.

### BACKGROUND OF THE INVENTION

The present invention relates to an array and a configuration of the array of traces on a printed wiring board for optimally controlling an impedance of differential signal lines.

Recently, as shown in FIG. 2, two signal traces are arrayed substantially parallel to each other at regular interval on an interface such as USB or IEEE1394 and on traces of a circuit board using differential signals such as LVDS. It is necessary to keep an impedance of the substantially parallel arrayed traces within a prescribed range. It is further necessary to avoid that other traces on the circuit board affects the impedance of a pair of signal traces. Accordingly, in the conventional technique, no line is wired between the substantially parallel signal traces. Also, another trace is formed at a position spaced apart from the periphery of the substantially parallel signal traces.

In a case that a frequency of a signal flowing on the traces on the printed-wiring board exceeds 10 MHz, the signal transmission on the traces is described as a distributed constants. The distributed constants are expressed as resistance R, inductance L, capacitance C and conductance G per unit length of line. A characteristic impedance is used as a quantity characterizing the traces as the transmission lines, and mathematically expressed as following equation.

[Formula 1]

$$Zo = \sqrt{\frac{R + j ω L}{G + j ω C}}$$

When resistance R=0 and the conductance G=0 in Formula 1, the transmission line has no loss. A characteristic impedance of the signal lines is given by the following equation.

[Formula 2] (In the equation, the values of the capacitance C and the inductance L are measured for each unit length of line)

Zo=\sqrt{L/C}

A characteristic impedance of a micro-strip line structure of the printed wiring board is approximately expressed by the equation shown in FIG. 4. The characteristic impedance is determined by a relative dielectric constant (εᵣ), a thickness (h) and a trace width (W) of a dielectric material.

[Formula 3]

$$Zo = \frac{87}{\sqrt{{ϵ}_{r} + 1.41}} {l}_{n} ( \frac{5.98 h}{0.8 W + t} )$$

A differential impedance is an impedance of a pair of lines when those lines are driven by differential signals having opposite phases. As shown in FIG. 5, the differential impedance is defined by two times of the characteristic impedance Z0 and the mutual coupling capacitance between the pair of traces. Further, in case where, as shown in FIG. 6, traces 2 are located between the pair of signal traces 1 and outside the pair of signal traces 1, the pair or signal traces trace 1 are affected by the mutual coupling capacitance between them.

As seen from the formulae of the characteristic impedance Z0 and the differential impedance Zdiff shown in FIGS. 4 and 5, the impedance is higher as the trace width W is narrower, and the impedance is lower as the gap G between the traces is narrower.

The USB 2.0 standard prescribes that the characteristic impedance is 45Ω±10% and the differential impedance is 90Ω±10%. To secure those prescribed values, in the case of a 4-layered board whose insulation layer thickness “h” is 0.2 mm, the trace is manufactured in the manner that the trace width is 0.3 mm and the trace pitch is about 0.5 mm. In the case of the 2-layered board having a thickness “h” of 1.6 mm, the trace manufactured in the matter that the trace width is 3 mm and the trace pitch is 20 mm or longer. Accordingly, the trace area of the board is large, so that the board size is large. To increase a mounting density of other parts, a designer must use a board of four or more layers, which is high in cost.

### SUMMARY OF THE INVENTION

To solve the problems mentioned above, there is provided a printed wiring board, on which a pair of signal traces for transmitting differential signals are mounted, wherein a trace connected to a line maintained at a fixed potential is arranged between the pair of signal traces.

In the present invention, an impedance of differential signal traces on a printed wiring board is controlled in a manner that a ground trace or a power source trace is arranged between the signal traces. Therefore, a designer can design traces each of which has a practical total width and impedance controlled even on the 2-layered board, a multilayered board including a ground layer or a power source layer and a signal layer, and a board having a low relative dielectric constant.

To the impedance control, the conventional technique uses the multilayered board. However, the present invention can control, as desired, the impedance of the signal traces even on the inexpensive board, such as the 2-layered plate, with less board areas of the traces. Thus, the present invention provides a flexible impedance control method.

### BRIEF DESCRIPTION OF THE DRAWINGS

FIG. 1 is a diagram showing a configuration of an array of signal traces, which is designed according to the present invention;

FIG. 2 is a diagram showing a configuration of an array of signal traces which is designed based on a related array;

FIG. 3 is a diagram showing a configuration of an array of signal traces designed according to the invention;

FIG. 4 is a cross sectional view showing the board in connection with a formula of the characteristic impedance;

FIG. 5 is a cross sectional view showing the board in connection with a formula of the characteristic impedance; and

FIG. 6 is a cross sectional view showing the board in connection with a formula of the characteristic impedance.

### DESCRIPTION OF THE PREFERRED EMBODIMENT

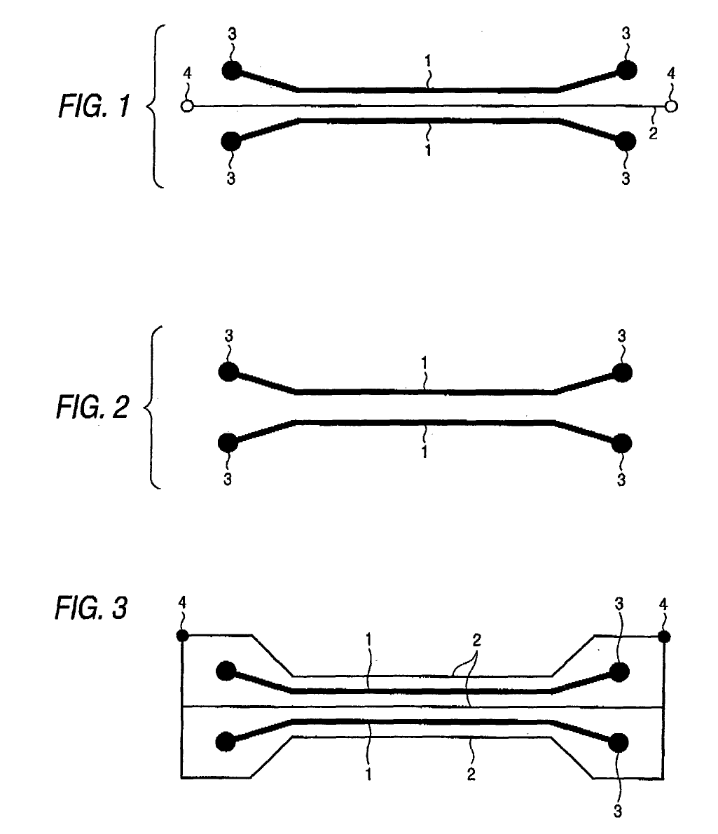

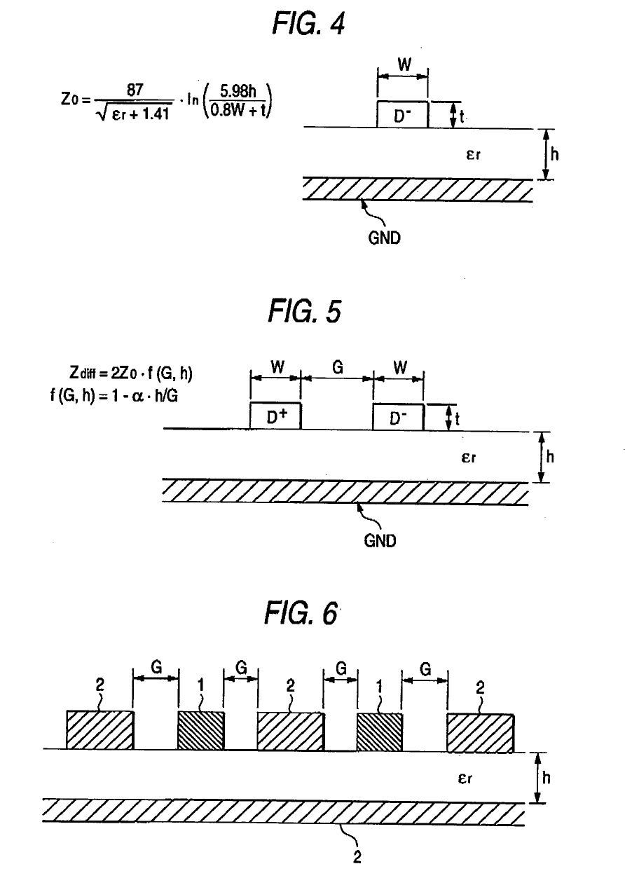

FIGS. 1 an 3 show traces (referred to as test coupons) formed on the same board for impedance measurement. Arrays, configurations and dimensions of the signal traces between the IC and connectors on the boards are exactly equal to those on actual boards. Each test coupon includes pads 3, which are provided on both ends thereof and to be brought into contact with a probe for measurement, and a pair of signal traces 1 arrayed parallel to each other. In the embodiment, the pair of signal traces 1, which are arrayed substantially parallel to each other, are connected to USB connectors. Those signal traces are served as two signal lines for transmitting and receiving data through the USB. Two signals which are opposite in phase, that is, differential signals, flow through those two signal lines.

Also in each of the trace arrays of the boards shown in FIGS. 1 and 3, a GND line 2 is provided on the same surface as that of the board on which the pair of signal traces 1 are arrayed substantially parallel to each other. In the board of FIG. 1, a GND line 2 is provided between the pair of signal traces 1. In the board of FIG. 3, in addition to the configuration of FIG. 1, GND lines 2 are provided also outside of the pair of signal traces 1 Via holes 4 are formed in the GND lines 2 shown in FIG. 3. For example, the via holes 4 are connected to the layers of the GND lines 2, which are formed on the reverse side of the board shown in FIG. 6.

The characteristic impedance and the differential impedance become higher as the width W of the trace is narrower, and becomes lower as the trace gap G becomes narrower. With the trace arrays configured, the characteristic impedance and the differential impedance can be obtained as desired, while reducing the signal trace width W, the signal trace gap G on the board, and a total area of the traces.

A case where a GNU line 2 is provided between the pair of signal traces 1 and another case where no GND line 2 is provided between them shown in FIGS. 5 and 6, were compared to secure the USB 2.0 standard (the characteristic impedance was 45Ω±10% and the differential impedance was 90Ω±10%). The boards used were made of the same kind of material. A thickness of each board was 1.6 mm (h=1.6 mm).

In the case of FIG. 6, the trace width (each trace) W=1.4 mm, and each trace gap G=0.15 mm, the width of the GND line 2 between the pair of signal traces 1 was 1 mm, and the width of each of the GND lines 2 located outside of the pair of signal traces 1 was 0.15 mm. Accordingly, a distance from the external end of the GND line 2 located outside of one of the pair of signal traces 1 to the external end of the GND line 2 located outside of the other was 4.7 mm (=1.4×2+1.0+0.15×2+0.15×4).

In the case of FIG. 5, the trace width W=3.4 mm and the trace gap G=7.0 mm. As a result, a distance from the external end of one of the pair of signal traces 1 to the external end of the other was 13.8 mm (=3.4×2+7.0).

As seen from the comparison, to secure the USB 2.0 standard values, in the trace array where the GND line 2 is located between the pair of signal traces 1 shown in FIG. 6, the trace area on the board is narrower than that in the trace array where no line is provided therebetween.

In the embodiment, the pair of signal traces 1 are data lines to which differential signals are input to and output from the USB connectors. If required, the pair of signal traces 1 may be used for the traces on the circuit board which handles other types of differential signals such as IEEE 1394 and LVDS.

In the embodiments, the GND line 2 is provided between the pair of signal traces 1. Also, the GND line 2 is provided between the pair of signal traces 1 and outside both of the pair of signal traces 1. However, the GND line 2 may be any line if it is held at a fixed potential. For example, it may be a trace connected to a DC power source. The GND lines 2 located outside of the pair of signal traces are not limited to the line having a fixed width. For example, the GND lines 2 located outside of the pair of signal traces may have a solid-surface.

What is claimed is:

1. A printed wiring board, on which two signal traces for a transmitting differential signal are mounted, wherein a trace connected to a line maintained at a fixed potential is arranged between the pair of signal traces.

2. The printed wiring board as set forth in claim 1, wherein a trace connected to a line maintained at a fixed potential is arranged at least one of both outsides of the pair of signal traces.

3. The printed wiring board as set forth in claim 1, wherein the line maintained at a fixed potential is a ground line.

4. The printed wiring board as set forth in claim 1, wherein a ground layer is formed on the reverse side of the printed wiring board.

5. The printed wiring board as set forth in claim 1, wherein the signal traces are connected to a USB connector.
